(19) United States
(12) Patent Application Publication
(10) Pub. No.: US 2023/0272550 A1
(43) Pub. Date: Aug. 31, 2023

(54) SILICON CARBIDE EPITAXIAL SUBSTRATE

(71) Applicant: SUMITOMO ELECTRIC INDUSTRIES, LTD., Osaka (JP)

(72) Inventors: Takaya MIYASE, Osaka (JP); Taro NISHIGUCHI, Osaka (JP)

(21) Appl. No.: 18/016,333

(22) PCT Filed: Jun. 29, 2021
(86) PCT No.: PCT/JP2021/024523

§ 371 Date: Jan. 14, 2023

(30) Foreign Application Priority Data
Jul. 22, 2020 (JP) 2020-125075

(51) Int. Cl. C30B 25/20; C30B 29/36

(52) U.S. Cl. CPC C30B 25/20; C30B 29/36

(57) ABSTRACT

When an area density of a first protrusion present in a central region is denoted by Xa, an area density of a second protrusion present in the central region is denoted by Xb, an area density of a third protrusion present in the central region is denoted by Xc, an area density of a fourth protrusion present in an outer circumferential region is denoted by Ya, an area density of a fifth protrusion present in the outer circumferential region is denoted by Yb, and an area density of a sixth protrusion present in the outer circumferential region is denoted by Yc, as viewed in a thickness direction of a silicon carbide substrate, the first protrusion and the fourth protrusion each have an area of 100 μm² or more and less than 1,000 μm².

### TECHNICAL FIELD

The present disclosure relates to a silicon carbide epitaxial substrate. This application claims priority based on Japanese Patent Application No. 2020-125075 filed on Jul. 22, 2020. The entire contents of the Japanese patent application are incorporated herein by reference.

### BACKGROUND ART

Japanese Unexamined Patent Application Publication No. 2019-46855 (PTL1) describes a method of forming a silicon carbide epitaxial film using CVD (Chemical Vapor Deposition).

### CITATION LIST

### Patent Literature

PTL 1: Japanese Unexamined Patent Application Publication No. 2019-46855

### SUMMARY OF INVENTION

A silicon carbide epitaxial substrate according to the present disclosure includes a silicon carbide substrate, a silicon carbide epitaxial layer and a backside surface. The silicon carbide epitaxial layer is disposed on the silicon carbide substrate. The backside surface is disposed opposite to the silicon carbide epitaxial layer with respect to the silicon carbide substrate. The backside surface includes a central region having a radius equal to ⅔ of a radius of the backside surface and surrounded by a circle centered at a center of the backside surface and an outer circumferential region surrounding the central region. When an area density of a first protrusion present in the central region is denoted by Xa, an area density of a second protrusion present in the central region is denoted by Xb, an area density of a third protrusion present in the central region is denoted by Xc, an area density of a fourth protrusion present in the outer circumferential region is denoted by Ya, an area density of a fifth protrusion present in the outer circumferential region is denoted by Yb, and an area density of a sixth protrusion present in the outer circumferential region is denoted by Yc, as viewed in a thickness direction of the silicon carbide substrate, the first protrusion and the fourth protrusion each have an area of 100 μm² or more and less than 1,000 μm², the second protrusion and the fifth protrusion each have an area of 1,000 μm² or more and less than 5,000 μm², and the third protrusion and the sixth protrusion each have an area of 5,000 μm² or more. The backside surface has a diameter of 100 mm or more, a value determined by dividing Xa by (Xa+Ya) is 0.3 or more and 0.5 or less, Xc is 10.0/cm² or less, and Yc is 12.0/cm² or less.

### BRIEF DESCRIPTION OF DRAWINGS

FIG. 1 is a schematic plan view showing the structure of a silicon carbide epitaxial substrate according to an embodiment of the present disclosure.

FIG. 2 is a schematic cross-sectional view taken along a line II-II of FIG. 1.

FIG. 3 is an enlarged schematic view of a region III of FIG. 2.

FIG. 4 is an enlarged schematic view of a region IV of FIG. 2.

FIG. 5 is a schematic plan view of region IV of FIG. 2.

FIG. 6 is an enlarged schematic view of a region VI of FIG. 2.

FIG. 7 is an enlarged schematic view of a region VII of FIG. 2.

FIG. 8 is an enlarged schematic view of a region VIII of FIG. 2.

FIG. 9 is an enlarged schematic view of a region IX of FIG. 2.

FIG. 10 is an enlarged schematic view of a region X of FIG. 2.

FIG. 11 is a schematic plan view of region X of FIG. 2.

FIG. 12 is an enlarged schematic view of a region XII of FIG. 2.

FIG. 13 is an enlarged schematic view of a region XIII of FIG. 2.

FIG. 14 is an enlarged schematic view of a region XIV of FIG. 2.

FIG. 15 is a schematic cross-sectional view showing the structure of a susceptor used in a method of manufacturing a silicon carbide epitaxial substrate according to the embodiment of the present disclosure.

FIG. 16 is a schematic plan view showing the structure of a susceptor used in the method of manufacturing a silicon carbide epitaxial substrate according to the embodiment of the present disclosure.

FIG. 17 is a schematic cross-sectional view showing a silicon carbide substrate placed on the susceptor.

### DETAILED DESCRIPTION

### Problem to be Solved by the Present Disclosure

An object of the present disclosure is to provide a silicon carbide epitaxial substrate capable of suppressing adsorption failure.

### Advantageous Effect of the Present Disclosure

According to the present disclosure, it is possible to provide a silicon carbide epitaxial substrate capable of suppressing adsorption failure.

### Summary of Embodiments of the Present Disclosure

First, an outline of embodiments of the present disclosure will be described. Regarding crystallographic indications in the present specification, an individual orientation is represented by [ ], a group orientation is represented by < >, an individual plane is represented by ( ), and a group plane is represented by { }. A negative crystallographic index is usually indicated by putting “−” (bar) above a numeral but is indicated by putting the negative sign before the numeral in the present specification.
(1) A silicon carbide epitaxial substrate 100 according to the present disclosure includes a silicon carbide substrate 10, a silicon carbide epitaxial layer 20, and a backside surface 30. Silicon carbide epitaxial layer 20 is disposed on silicon carbide substrate 10. Backside surface 30 is disposed opposite to silicon carbide epitaxial layer 20 with respect to silicon carbide substrate 10. Backside surface 30 includes a central region 32 having a radius equal to ⅔ of a radius of backside surface 30 and surrounded by a circle centered at a center 16 of backside surface 30 and an outer circumferential region 31 surrounding central region 32. When an area density of a first protrusion 1 present in central region 32 is denoted by Xa, an area density of a second protrusion 2 present in central region 32 is denoted by Xb, an area density of a third protrusion 3 present in central region 32 is denoted by Xc, an area density of a fourth protrusion 4 present in outer circumferential region 31 is denoted by Ya, an area density of a fifth protrusion 5 present in outer circumferential region 31 is denoted by Yb, and an area density of a sixth protrusion 6 present in outer circumferential region 31 is denoted by Yc, as viewed in a thickness direction of silicon carbide substrate 10, first protrusion 1 and fourth protrusion 4 each have an area of 100 μm² or more and less than 1,000 μm², second protrusion 2 and fifth protrusion 5 each have an area of 1,000 μm² or more and less than 5,000 μm², and third protrusion 3 and sixth protrusion 6 each have an area of 5,000 μm² or more. Backside surface 30 has a diameter of 100 mm or more, a value determined by dividing Xa by (Xa+Ya) is 0.3 or more and 0.5 or less, Xc is 10.0/cm² or less, and Yc is 12.0/cm² or less.

When there are a plurality of first protrusions 1 and a plurality of fourth protrusions 4, the area of each of first protrusions 1 and fourth protrusions 4 being 100 μm² or more and less than 1,000 μm² means that the area of each of the plurality of first protrusions 1 is 100 μm² or more and less than 1,000 μm², and the area of each of the plurality of fourth protrusions 4 is 100 μm² or more and less than 1,000 μm². Similarly, when there are a plurality of second protrusions 2 and a plurality of fifth protrusions 5, the area of each of second protrusions 2 and fifth protrusions 5 being 1,000 μm² or more and less than 5,000 μm² means that the area of each of the plurality of second protrusions 2 is 1,000 μm² or more and less than 5,000 μm² and the area of each of the plurality of fifth protrusions 5 is 1,000 μm² or more and less than 5,000 μm². Similarly, when there are a plurality of third protrusions 3 and a plurality of sixth protrusions 6, the area of each of third protrusions 3 and sixth protrusions 6 being 5,000 μm² or more means that the area of each of the plurality of third protrusions 3 is 5,000 μm² or more and the area of each of the plurality of sixth protrusions 6 is 5,000 μm² or more.
(2) In silicon carbide epitaxial substrate 100 according to (1) above, Yb may be 30.0/cm² or less.
(3) In silicon carbide epitaxial substrate 100 according to (1) or (2) above, Xc may be 3.0/cm² or less.
(4) In silicon carbide epitaxial substrate 100 according to any one of (1) to (3) above, Xb may be 20.0/cm² or less.
(5) In silicon carbide epitaxial substrate 100 according to any one of (1) to (4) above, Yc may be 4.0/cm² or less.
(6) In silicon carbide epitaxial substrate 100 according to any one of (1) to (5) above, third protrusion 3 and sixth protrusion 6 may contain polycrystalline silicon carbide.
(7) In silicon carbide epitaxial substrate 100 according to any one of (1) to (6) above, second protrusion 2 and fifth protrusion 5 may contain polycrystalline silicon carbide.
(8) In silicon carbide epitaxial substrate 100 according to any one of (1) to (7) above, first protrusion 1 and fourth protrusion 4 may contain polycrystalline silicon carbide.
(9) In silicon carbide epitaxial substrate 100 according to any one of (1) to (8) above, the value determined by dividing Xa by (Xa+Ya) may be 0.4 or less.

### Details of Embodiments of Present Disclosure

Hereinafter, embodiments of the present disclosure will be described in detail. In the following description, the same or corresponding elements are denoted by the same reference numerals, and the same description thereof will not be repeated.

(Silicon Carbide Epitaxial Substrate)

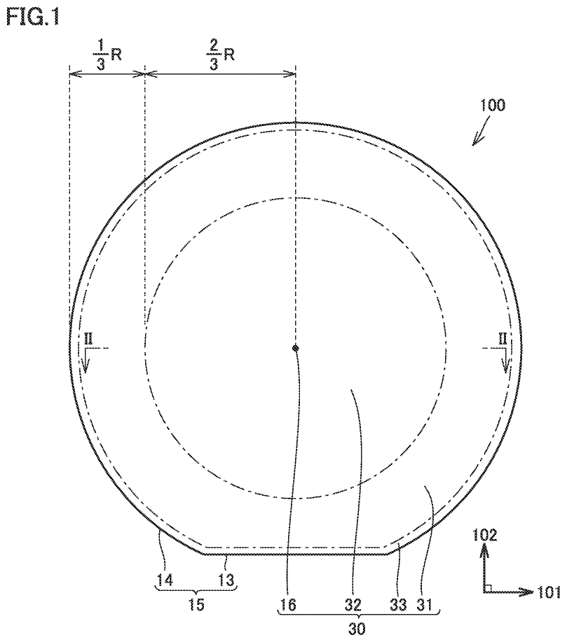

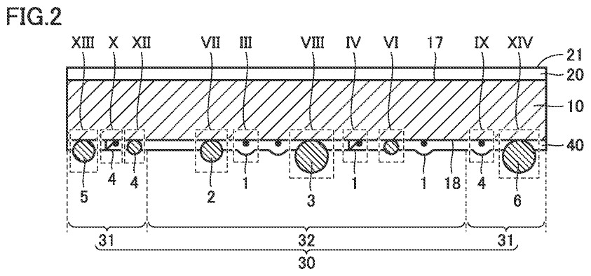

FIG. 1 is a schematic plan view showing the structure of a silicon carbide epitaxial substrate 100 according to an embodiment of the present disclosure. FIG. 2 is a schematic cross-sectional view taken along a line II-II of FIG. 1. As shown in FIGS. 1 and 2, silicon carbide epitaxial substrate 100 according to an embodiment of the present disclosure includes a silicon carbide substrate 10, a first silicon carbide epitaxial layer 20, a second silicon carbide epitaxial layer 40, and an outer circumferential edge 15. Silicon carbide substrate 10 has a first main surface 17 and a second main surface 18. Second main surface 18 is disposed opposite to first main surface 17.

First silicon carbide epitaxial layer 20 is disposed on silicon carbide substrate 10. First silicon carbide epitaxial layer 20 is in contact with silicon carbide substrate 10 at first main surface 17. First main surface 17 is an interface between silicon carbide substrate and first silicon carbide epitaxial layer 20. First silicon carbide epitaxial layer 20 forms a surface of silicon carbide epitaxial substrate 100 (third main surface 21). When a silicon carbide semiconductor device (not shown) is manufactured using silicon carbide epitaxial substrate 100, a drift region (not shown), a base region (not shown), a source region (not shown), a gate electrode (not shown), or a gate insulating film (not shown) may be formed on third main surface 21.

As shown in FIG. 2, second silicon carbide epitaxial layer 40 is in contact with silicon carbide substrate 10 at second main surface 18. Silicon carbide epitaxial substrate 100 has a backside surface 30. Backside surface 30 is disposed opposite to silicon carbide epitaxial layer 20 with respect to silicon carbide substrate 10. Second silicon carbide epitaxial layer 40 forms a portion of backside surface 30 of silicon carbide epitaxial substrate 100. Silicon carbide substrate 10 is disposed between first silicon carbide epitaxial layer 20 and second silicon carbide epitaxial layer 40.

As shown in FIG. 1, backside surface 30 includes a central region 32, an outer circumferential region 31, and an edge region 33. Central region 32 is a region having a radius equal to ⅔ of a radius R of backside surface 30 and surrounded by a circle centered at a center 16 of backside surface 30. Outer circumferential region 31 surrounds central region 32. As viewed in a direction perpendicular to first main surface 17 (in other words, as viewed in the thickness direction of silicon carbide substrate 10), outer circumferential region 31 is a ring-shaped region. As shown in FIG. 1, the radius of the outer circumference of central region 32 (the boundary between outer circumferential region 31 and central region 32) is equal to ⅔ of radius R of backside surface 30. Edge region 33 is a region within 3 mm from outer circumferential edge 15 toward center 16 of backside surface 30. Outer circumferential region 31 is a region sandwiched between central region 32 and edge region 33.

Outer circumferential edge 15 has, for example, an orientation flat 13 and an arc-shaped portion 14. Orientation flat 13 extends along a first direction 101. As shown in FIG. 1, orientation flat 13 is linear, as viewed in a direction perpendicular to first main surface 17. Arc-shaped portion 14 is contiguous to orientation flat 13. Arc-shaped portion 14 is arc-shaped when viewed in the direction perpendicular to first main surface 17. Center 16 of backside surface 30 is located at the center of the circle containing arc-shaped portion 14 as viewed in the direction perpendicular to first main surface 17.

As shown in FIG. 1, as viewed in the direction perpendicular to first main surface 17, backside surface 30 extends along each of first direction 101 and a second direction 102. As viewed in the direction perpendicular to first main surface 17, first direction 101 is a direction perpendicular to second direction 102.

First direction 101 is, for example, a <11-20> direction. First direction 101 may be, for example, a [11-20] direction. First direction 101 may be a direction obtained by projecting the <11-20> direction onto first main surface 17. In other words, first direction 101 may be, for example, a direction including a <11-20> direction component.

Second direction 102 is, for example, a <1-100> direction. Second direction 102 may be, for example, a [1-100] direction. Second direction 102 may be, for example, a direction obtained by projecting the <1-100> direction onto first main surface 17. In other words, second direction 102 may be, for example, a direction including a <1-100> direction component.

First main surface 17 may be a {0001} plane or a surface inclined with respect to the {0001} plane. When first main surface 17 is inclined with respect to the {0001} plane, an angle of inclination (off angle) with respect to the {0001} plane is from 2° to 6°, for example. When first main surface 17 is inclined with respect to the {0001} plane, the inclination direction (off direction) of first main surface 17 is, for example, the <11-20>direction.

The diameter (maximum diameter) of backside surface 30 is 100 mm (4 inches) or more. The diameter of backside surface 30 may be 125 mm (5 inches) or more, or 150 mm (6 inches) or more. The upper limit of the diameter of backside surface 30 is not particularly limited, but may be, for example, 200 mm (8 inches) or less. The diameter (maximum diameter) of backside surface 30 is the longest linear distance between two different points on outer circumferential edge 15. The diameter of backside surface 30 may be a diameter of outer circumferential edge 15 (i.e., arc-shaped portion 14) excluding orientation flat 13.

As used herein, 4 inches refers to 100 mm or 101.6 mm (4 inches×25.4 mm/inch). Five inches refers to 125 mm or 127.0 mm (5 inches×25.4 mm/inch). 6 inches refers to 150 mm or 152.4 mm (6 inches×25.4 mm/inch). 8 inches refers to 200 mm or 203.2 mm (8 inches×25.4 mm/inch).

The polytype of silicon carbide constituting silicon carbide substrate 10 is, for example, 4H. Similarly, the polytype of silicon carbide constituting first silicon carbide epitaxial layer 20 is, for example, 4H. Similarly, the polytype of silicon carbide constituting second silicon carbide epitaxial layer 40 is, for example, 4H. The thickness of silicon carbide substrate 10 is, for example, from 350 μm to 500 μm. The thickness of first silicon carbide epitaxial layer 20 may be less than the thickness of silicon carbide substrate 10. The thickness of second silicon carbide epitaxial layer 40 may be less than the thickness of silicon carbide substrate 10.

Silicon carbide substrate 10 contains an n-type impurity, for example, such as nitrogen (N). The conductivity type of silicon carbide substrate 10 is, for example, n-type. First silicon carbide epitaxial layer 20 contains an n-type impurity, for example, such as nitrogen. The conductivity type of first silicon carbide epitaxial layer 20 is, for example, n-type. The concentration of the n-type impurity included in first silicon carbide epitaxial layer 20 may be lower than the concentration of the n-type impurity included in silicon carbide substrate 10. Second silicon carbide epitaxial layer 40 contains an n-type impurity such as nitrogen. The conductivity type of second silicon carbide epitaxial layer 40 is, for example, n-type. The concentration of the n-type impurity included in second silicon carbide epitaxial layer 40 may be lower than the concentration of the n-type impurity included in silicon carbide substrate 10.

As shown in FIG. 2, silicon carbide epitaxial substrate 100 has, for example, a first protrusion 1, a second protrusion 2, a third protrusion 3, a fourth protrusion 4, a fifth protrusion 5, and a sixth protrusion 6. First protrusion 1 is present in central region 32. Second protrusion 2 is present in central region 32. Third protrusion 3 is present in central region 32. Fourth protrusion 4 is present in outer circumferential region 31. Fifth protrusion 5 is present in outer circumferential region 31. Sixth protrusion 6 is present in outer circumferential region 31.

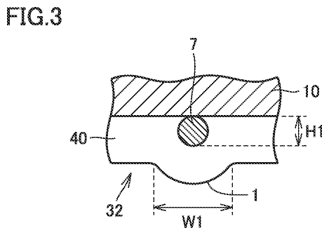

FIG. 3 is an enlarged schematic view of region III of FIG. 2. As shown in FIG. 3, silicon carbide epitaxial substrate 100 has a first particle 7. First particle 7 may be in contact with silicon carbide substrate 10 at second main surface 18. Second silicon carbide epitaxial layer 40 may cover first particle 7. First particle 7 may be sandwiched between silicon carbide substrate 10 and second silicon carbide epitaxial layer 40. First particle 7 is, for example, a downfall. First particle 7 may include a polycrystalline silicon carbide. First particle 7 may contain carbon. The height (first height H1) of first particle 7 is, for example, 1 μm or more and less than 40 μm.

As shown in FIG. 3, first protrusion 1 may be formed by second silicon carbide epitaxial layer 40. First protrusion 1 may be formed on a surface of second silicon carbide epitaxial layer 40 facing first particle 7. As viewed in the thickness direction of silicon carbide substrate 10, an area of first protrusion 1 is 100 μm² or more and less than 1000 μm². When there are a plurality of first protrusions 1, the area of first protrusion 1 refers to the area of each of the plurality of first protrusions 1. First protrusion 1 has a maximum width (first maximum width W1) of, for example, 11 μm or more and less than 36 μm. First protrusion 1 constitutes a part of central region 32. The maximum width of the protrusion is the longest linear distance between two different points on the outer periphery of the protrusion when the protrusion is viewed in a direction perpendicular to second main surface 18.

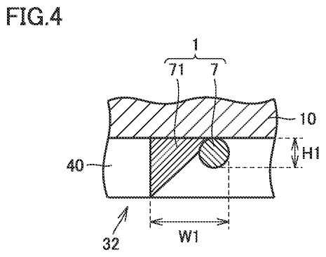

FIG. 4 is an enlarged schematic view of a region IV of FIG. 2. As shown in FIG. 4, first protrusion 1 may have first particle 7 and a first defect 71. First defect 71 is a defect grown from first particle 7 in a step flow direction in accordance with epitaxial growth. First defect 71 is contiguous to first particle 7. First defect 71 is, for example, a stacking fault. First defect 71 may be a triangular defect. First defect 71 may be exposed on the surface of second silicon carbide epitaxial layer 40.

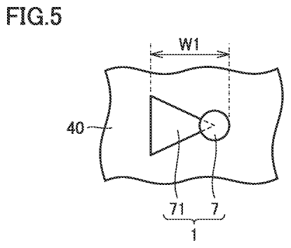

FIG. 5 is a schematic plan view of region IV of FIG. 2. As shown in FIG. 5, as viewed in the thickness direction of silicon carbide substrate 10, the shape of first defect 71 is, for example, triangular. As viewed in the thickness direction of silicon carbide substrate 10, one of the vertices of the triangle overlaps first particle 7. As viewed in the thickness direction of silicon carbide substrate 10, a distance between two sides of the triangle may increase with increasing distance from first particle 7. As viewed in the thickness direction of silicon carbide substrate 10, the area of first protrusion 1 is a value obtained by subtracting the area of the overlapping portion between first particle 7 and first defect 71 from the sum of the area of circular first particle 7 and the area of triangular first defect 71.

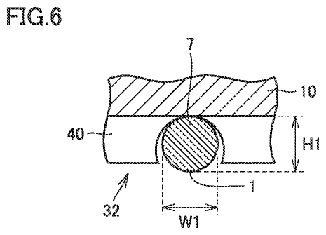

FIG. 6 is an enlarged schematic view of a region VI of FIG. 2. As shown in FIG. 6, first protrusion 1 may be, for example, a downfall. First protrusion 1 may include a polycrystalline silicon carbide. First protrusion 1 may include carbon. First protrusion 1 may be composed of first particle 7. First protrusion 1 may be in contact with silicon carbide substrate 10 at second main surface 18. Second silicon carbide epitaxial layer 40 may surround a portion of a side surface of first protrusion 1.

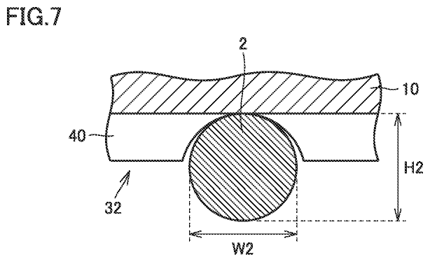

FIG. 7 is an enlarged schematic view of a region VII of FIG. 2. As shown in FIG. 7, second protrusion 2 is, for example, a downfall. Second protrusion 2 may include a polycrystalline silicon carbide. Second protrusion 2 may include carbon. Second protrusion 2 may be in contact with silicon carbide substrate 10 at second main surface 18. Second silicon carbide epitaxial layer 40 may surround a portion of a side surface of second protrusion 2. The height of second protrusion 2 (second height H2) is, for example, 20 μm or more and less than 100 μm. Second height H2 may be greater than first height H1.

As shown in FIG. 7, second protrusion 2 is exposed from second silicon carbide epitaxial layer 40. The side surface of second protrusion 2 may be separated from second silicon carbide epitaxial layer 40, or may be in contact with second silicon carbide epitaxial layer 40. As viewed in the thickness direction of silicon carbide substrate 10, an area of second protrusion 2 is 1000 μm² or more and less than 5000 μm². When there are a plurality of second protrusions 2, the area of second protrusion 2 refers to the area of each of the plurality of second protrusions 2. Second protrusion 2 has a maximum width (second maximum width W2) of, for example, 36 μm or more and less than 80 μm. Second protrusion 2 constitutes a part of central region 32. Second maximum width W2 may be greater than first maximum width W1.

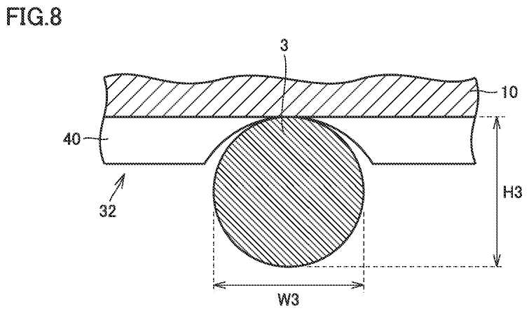

FIG. 8 is an enlarged schematic view of region VIII of FIG. 2. As shown in FIG. 8, third protrusion 3 is, for example, a downfall. Third protrusion 3 may include a polycrystalline silicon carbide. Third protrusion 3 may include carbon. Third protrusion 3 may be in contact with silicon carbide substrate 10 at second main surface 18. Second silicon carbide epitaxial layer 40 may surround a portion of a side surface of third protrusion 3. The height of third protrusion 3 (third height H3) is, for example, 60 μm or more. Third height H3 may be greater than second height H2.

As shown in FIG. 8, third protrusion 3 is exposed from second silicon carbide epitaxial layer 40. The side surface of third protrusion 3 may be separated from second silicon carbide epitaxial layer 40, or may be in contact with second silicon carbide epitaxial layer 40. As viewed in the thickness direction of silicon carbide substrate 10, the area of third protrusion 3 is 5000 μm² or more. When there are a plurality of third protrusions 3, the area of third protrusion 3 refers to the area of each of the plurality of third protrusions 3. Third protrusion 3 has a maximum width (third maximum width W3) of, for example, 80 μm or more. Third protrusion 3 constitutes a part of central region 32. Third maximum width W3 may be greater than second maximum width W2.

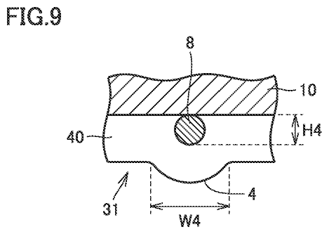

FIG. 9 is an enlarged schematic view of region 1X of FIG. 2. As shown in FIG. 9, silicon carbide epitaxial substrate 100 has a second particle 8. Second particle 8 may be in contact with silicon carbide substrate 10 at second main surface 18. Second silicon carbide epitaxial layer 40 covers second particle 8. Second particle 8 is sandwiched between silicon carbide substrate 10 and second silicon carbide epitaxial layer 40. Second particle 8 is, for example, a downfall. Second particle 8 may include a polycrystalline silicon carbide. Second particle 8 may contain carbon. The height of second particle 8 (fourth height H4) is, for example, 1 μm or more and less than 40 μm.

As shown in FIG. 9, fourth protrusion 4 may be composed of second silicon carbide epitaxial layer 40. Fourth protrusion 4 may be formed on a surface of second silicon carbide epitaxial layer 40 facing second particle 8. As viewed in the thickness direction of silicon carbide substrate 10, an area of fourth protrusion 4 is 100 μm² or more and less than 1000 μm². When there are a plurality of fourth protrusions 4, the area of fourth protrusion 4 refers to the area of each of the plurality of fourth protrusions 4. Fourth protrusion 4 has a maximum width (fourth maximum width W4) of, for example, 11 μm or more and less than 36 μm. Fourth protrusion 4 constitutes a part of outer circumferential region 31.

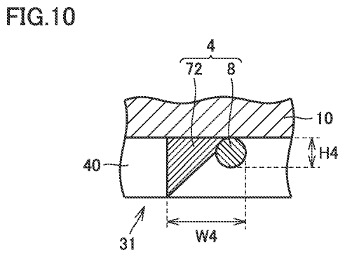

FIG. 10 is an enlarged schematic view of region X of FIG. 2. As shown in FIG. 10, fourth protrusion 4 may have second particle 8 and a second defect 72. Second defect 72 is a defect grown from second particle 8 in the step flow direction in accordance with epitaxial growth. Second defect 72 is contiguous to second particle 8. Second defect 72 is, for example, a stacking fault. Second defect 72 may be a triangular defect. Second defect 72 may be exposed on the surface of second silicon carbide epitaxial layer 40.

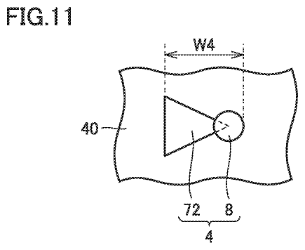

FIG. 11 is a schematic plan view of a region X of FIG. 2. As shown in FIG. 11, as viewed in the thickness direction of silicon carbide substrate 10, the shape of second defect 72 is, for example, a triangle. As viewed in the thickness direction of silicon carbide substrate 10, one of the vertices of the triangle overlaps second particle 8. As viewed in the thickness direction of silicon carbide substrate 10, a distance between two sides of the triangle may increase with increasing distance from second particle 8. As viewed in the thickness direction of silicon carbide substrate 10, the area of fourth protrusion 4 is a value obtained by subtracting the area of the overlapping portion between second particle 8 and second defect 72 from the sum of the area of circular second particle 8 and the area of triangular second defect 72.

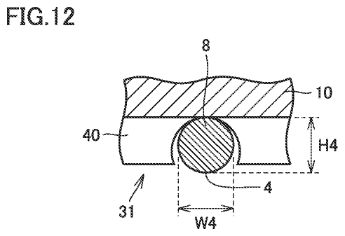

FIG. 12 is an enlarged schematic view of a region XII of FIG. 2. As shown in FIG. 12, fourth protrusion 4 may be, for example, a downfall. Fourth protrusion 4 may include a polycrystalline silicon carbide. Fourth protrusion 4 may include carbon. Fourth protrusion 4 may be composed of second particle 8. Fourth protrusion 4 may be in contact with silicon carbide substrate 10 at second main surface 18. Second silicon carbide epitaxial layer 40 may surround a portion of a side surface of fourth protrusion 4.

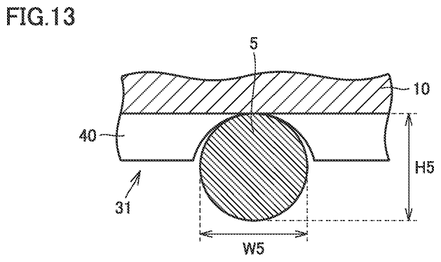

FIG. 13 is an enlarged schematic view of a region XIII of FIG. 2. As shown in FIG. 13, fifth protrusion 5 is, for example, a downfall. Fifth protrusion 5 may include a polycrystalline silicon carbide. Fifth protrusion 5 may include carbon. Fifth protrusion 5 may be in contact with silicon carbide substrate 10 at second main surface 18. Second silicon carbide epitaxial layer 40 may surround a portion of a side surface of fifth protrusion 5. The height of fifth protrusion 5 (fifth height H5) is, for example, 20 μm or more and less than 100 μm. Fifth height H5 may be greater than fourth height H4.

As shown in FIG. 13, fifth protrusion 5 is exposed from second silicon carbide epitaxial layer 40. The side surface of fifth protrusion 5 may be separated from second silicon carbide epitaxial layer 40, or may be in contact with second silicon carbide epitaxial layer 40. As viewed in the thickness direction of silicon carbide substrate 10, the area of fifth protrusion 5 is 1000 μm² or more and less than 5000 μm². When there are a plurality of fifth protrusions 5, the area of fifth protrusion 5 refers to the area of each of the plurality of fifth protrusions 5. Fifth protrusion 5 has a maximum width (fifth maximum width W5) of, for example, 36 μm or more and less than 80 μm. Fifth protrusion 5 constitutes a part of outer circumferential region 31. Fifth maximum width W5 may be greater than fourth maximum width W4.

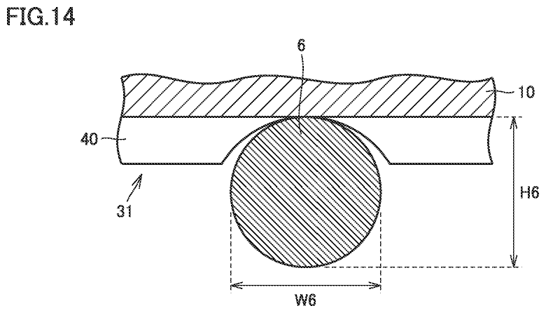

FIG. 14 is an enlarged schematic view of region XIV of FIG. 2. As shown in FIG. 14, sixth protrusion 6 is, for example, a downfall. Sixth protrusion 6 may include a polycrystalline silicon carbide. Sixth protrusion 6 may include carbon. Sixth protrusion 6 may be in contact with silicon carbide substrate 10 at second main surface 18. Second silicon carbide epitaxial layer 40 may surround a portion of a side surface of sixth protrusion 6. The height of sixth protrusion 6 (sixth height H6) is, for example, 60 μm or more. Sixth height H6 may be greater than fifth height H5.

As shown in FIG. 14, sixth protrusion 6 is exposed from second silicon carbide epitaxial layer 40. The side surface of sixth protrusion 6 may be separated from second silicon carbide epitaxial layer 40 or may be in contact with second silicon carbide epitaxial layer 40. As viewed in the thickness direction of silicon carbide substrate 10, an area of sixth protrusion 6 may be 5000 μm² or more. When there are a plurality of sixth protrusions 6, the area of sixth protrusion 6 refers to the area of each of the plurality of sixth protrusions 6. Sixth protrusion 6 has a maximum width (sixth maximum width W6) of, for example, 80 μm or more. Sixth protrusion 6 constitutes a part of outer circumferential region 31. Sixth maximum width W6 may be greater than fifth maximum width W5.

In silicon carbide epitaxial substrate 100 according to the embodiment of the present disclosure, when the area density of first protrusion 1 present in central region 32 is denoted by Xa, the area density of second protrusion 2 present in central region 32 is denoted by Xb, the area density of third protrusion 3 present in central region 32 is denoted by Xc, the area density of fourth protrusion 4 present in outer circumferential region 31 is denoted by Ya, the area density of fifth protrusion 5 present in outer circumferential region 31 is denoted by Yb, and the area density of sixth protrusion 6 present in outer circumferential region 31 is denoted by Yc, a value determined by dividing Xa by (Xa+Ya) is 0.3 or more and 0.5 or less, Xc is 10.0/cm² or less, and Yc is 12.0/cm² or less.

In silicon carbide epitaxial substrate 100 according to the embodiment of the present disclosure, Yb may be, for example, 30.0/cm² or less. Yb may be, for example, 20.0/cm² or less, or 10.0/cm² or less. The lower limit of Yb is not particularly limited, and may be, for example, 0.1/cm² or more, or 0.5/cm² or more.

According to silicon carbide epitaxial substrate 100 according to the embodiment of the present disclosure, Xc may be, for example, 3.0/cm² or less. Xc may be, for example, 2.0/cm² or less, or 1.0/cm² or less. The lower limit of Xc is not particularly limited, and may be, for example, 0.01/cm² or more, or 0.05/cm² or more.

According to silicon carbide epitaxial substrate 100 according to the embodiment of the present disclosure, Xb may be, for example, 20.0/cm² or less. Xb may be, for example, 16.0/cm² or less, or 8.0/cm² or less. The lower limit of Xb is not particularly limited, and may be, for example, 0.1/cm² or more, or 0.5/cm² or more.

According to silicon carbide epitaxial substrate 100 according to the embodiment of the present disclosure, Yc may be 4.0/cm² or less. Yc may be, for example, 3.0/cm² or less, or 2.0/cm² or less. The lower limit of Yc is not particularly limited, and may be, for example, 0.01/cm² or more, or 0.05/cm² or more.

According to silicon carbide epitaxial substrate 100 according to the embodiment of the present disclosure, Xa may be, for example, 800.0/cm² or less or 400.0/cm² or less. The lower limit of Xa is not particularly limited, and may be, for example, 0.1/cm² or more, or 1/cm² or more.

According to silicon carbide epitaxial substrate 100 according to the embodiment of the present disclosure, Ya may be, for example, 600.0/cm² or less or 400.0/cm² or less. The lower limit of Ya is not particularly limited, and may be, for example, 0.1/cm² or more, or 1/cm² or more.

According to silicon carbide epitaxial substrate 100 according to the embodiment of the present disclosure, a value determined by dividing Xa by (Xa+Ya) may be 0.45 or less or 0.4 or less.

(Method of Measuring Protrusion)

Next, a method of measuring the protrusion will be described. The protrusion can be identified by observing backside surface 30 of silicon carbide epitaxial substrate 100 using, for example, a defect inspection apparatus equipped with a confocal differential interference microscope. For example, WASAVI series “SICA 6X” manufactured by Lasertec Corporation can be used as a defect inspection apparatus including a confocal differential interference microscope. The magnification of the objective lens is 10 times, for example.

The protrusion is detected as a defect by SICA. The area of the detected defect is the area of the protrusion. In the case where a triangular defect or the like connected to the projection portion is involved, the area of the triangular defect is also included. When the protrusion is specified from the defect detected by the SICA, the measurement sensitivity of the SICA is adjusted in advance so that the protrusion can be detected. The protrusion is defined in consideration of typical planar shape, dimension, and the like of the protrusion. Based on the observed image, the protrusion is identified. “Thresh S” which is an index of the measurement sensitivity of the SICA is set to 40, for example.

A confocal differential interference microscope image of entire backside surface 30 is taken while moving silicon carbide epitaxial substrate 100 in a direction parallel to the surface of silicon carbide epitaxial substrate 100. In the acquired confocal differential interference microscope image, first protrusion 1, second protrusion 2, third protrusion 3, fourth protrusion 4, fifth protrusion 5, and sixth protrusion 6 are observed. In the acquired confocal differential interference contrast microscope image, the number of each of first protrusion 1, second protrusion 2, third protrusion 3, fourth protrusion 4, fifth protrusion 5, and sixth protrusion 6 is obtained. The values obtained by dividing the numbers of first protrusion 1, second protrusion 2, and third protrusion 3 by the measurement area in central region 32 are taken as the area densities of first protrusion 1, second protrusion 2, and third protrusion 3, respectively. Values obtained by dividing the numbers of fourth protrusion 4, fifth protrusion 5, and sixth protrusion 6 by the measurement area in outer circumferential region 31 are defined as the area densities of fourth protrusion 4, fifth protrusion 5, and sixth protrusion 6, respectively. Note that edge region 33 within 3 mm from outer circumferential edge 15 is excluded from the measurement region of the protrusion (edge exclusion).

(Method of Manufacturing Silicon Carbide Epitaxial Substrate)

Next, a method of manufacturing silicon carbide epitaxial substrate 100 according to the embodiment of the present disclosure will be described.

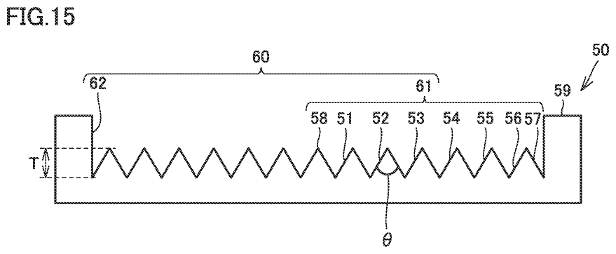

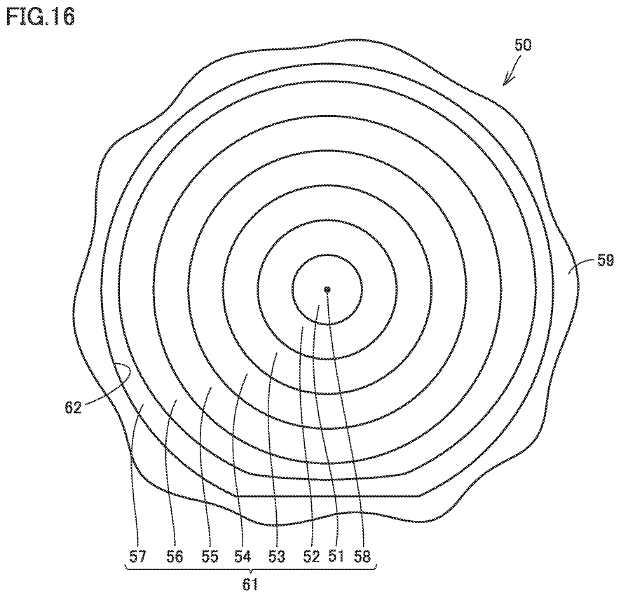

FIG. 15 is a schematic cross-sectional view showing the structure of a susceptor used in the method of manufacturing silicon carbide epitaxial substrate 100 according to the embodiment of the present disclosure. FIG. 16 is a schematic plan view showing the structure of the susceptor used in the method of manufacturing silicon carbide epitaxial substrate 100 according to the embodiment of the present disclosure. The material constituting the susceptor is, for example, silicon carbide.

As shown in FIGS. 15 and 16, a susceptor 50 is provided with a silicon carbide substrate placing member 60. Silicon carbide substrate placing member 60 is composed of a side surface 62 and a bottom surface 61. Side surface 62 is contiguous to a top surface 59 of susceptor 50. Bottom surface 61 is contiguous to side surface 62. Bottom surface 61 of silicon carbide substrate placing member 60 is formed with a plurality of concentrically arranged recesses. Specifically, the plurality of recesses include a first recess 51, a second recess 52, a third recess 53, a fourth recess 54, a fifth recess 55, a sixth recess 56, and a seventh recess 57. First recess 51 is formed so as to surround a central portion 58 of bottom surface 61. Second recess 52 is formed so as to surround first recess 51. Third recess 53 is formed so as to surround second recess 52. Fourth recess 54 is formed so as to surround third recess 53. Fifth recess 55 is formed so as to surround fourth recess 54. Sixth recess 56 is formed so as to surround fifth recess 55. Seventh recess 57 is formed so as to surround sixth recess 56.

As shown in FIG. 15, there is a protrusion between two adjacent recesses. An angle θ of the tip of the protrusion is, for example, from 30° to 45°. A height T of the protrusion is, for example, 100 μm or more.

Next, silicon carbide substrate 10 is prepared. For example, a silicon carbide single crystal having a polytype 4H is produced by a sublimation method. Next, the silicon carbide single crystal is sliced by, for example, a wire saw. Silicon carbide substrate 10 contains an n-type impurity such as nitrogen. The conductivity type of silicon carbide substrate 10 is, for example, n-type. Next, mechanical polishing, chemical mechanical polishing, and cleaning are performed on silicon carbide substrate 10. Thus, silicon carbide substrate 10 is prepared.

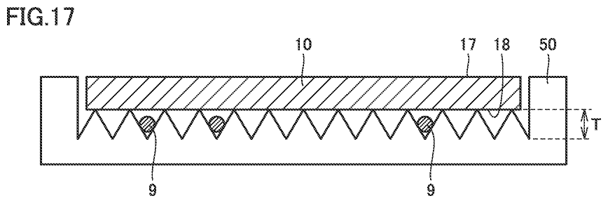

Next, silicon carbide substrate 10 is placed on susceptor 50. FIG. 17 is a schematic cross-sectional view showing silicon carbide substrate 10 placed on susceptor 50. First, susceptor 50 on which silicon carbide substrate 10 is placed in a CVD furnace. On the inner wall of the CVD furnace, deposition materials such as a crystal source material used in the previous epitaxial growth are adhered. The deposition material is, for example, silicon carbide particles or carbon particles. The inner wall of the CVD furnace is made of, for example, a carbon member.

By repeating the rise and fall of the temperature in the CVD furnace, deflection occurs in the carbon member constituting the inner wall. As a result, the deposition material adhering to the inner wall falls onto susceptor 50. The deposition material falling on susceptor 50 is referred to as a downfall. The downfall is generally particulate. The downfall is, for example, polycrystalline silicon carbide or carbon. The diameter of the downfall is, for example, in the range of 0.1 μm to 1 mm.

The downfall falls, for example, onto top surface 59 of susceptor 50. The downfall that has fallen onto top surface 59 of susceptor 50 moves to bottom surface 61 of silicon carbide substrate placing member 60 of susceptor 50. If there is a downfall on bottom surface 61 of susceptor 50, the downfall will adhere to backside surface 30 of silicon carbide substrate 10 when silicon carbide substrate 10 is placed on bottom surface 61 of silicon carbide substrate placing member 60.

As shown in FIG. 17, when a plurality of recesses are provided in bottom surface 61 of silicon carbide substrate placing member 60, downfalls 9 having a large diameter enter the interior of the recesses. Since silicon carbide substrate 10 is placed on apex of the protrusion, it does not touch a downfall 9 having a large diameter. Therefore, it is possible to prevent downfall 9 from adhering to the backside surface (second main surface 18) of silicon carbide substrate 10. There may be a downfall having a small diameter at the apex of the projection. The downfall having a small diameter is adhered to the backside surface (second main surface 18) of silicon carbide substrate 10. The size, area density, and the like of the downfall adhered to the backside surface (second main surface 18) of silicon carbide substrate 10 may be controlled by adjusting the depths of the recesses provided in bottom surface 61 of silicon carbide substrate placing member 60, the positions of the recesses, the area of the apex of the protrusion, the position of the protrusion, and the like.

Next, effects of silicon carbide epitaxial substrate 100 according to the embodiment of the present disclosure will be described.

A process of manufacturing a silicon carbide semiconductor device using silicon carbide epitaxial substrate 100 generally includes an exposure step and an inspection step. During these steps, backside surface 30 of silicon carbide epitaxial substrate 100 is adsorbed to a chuck. As the chuck, a vacuum chuck, an electrostatic chuck or the like is generally used. For example, adsorption failure of silicon carbide epitaxial substrate 100 to the chuck in the exposure step causes exposure failure. As a result of diligent studies on the cause of adsorption failure of silicon carbide epitaxial substrate 100 to the chuck, the inventors have obtained the following findings.

First, the inventors focused on the size and position of the protrusions present on backside surface 30 of silicon carbide epitaxial substrate 100. Specifically, the protrusions were classified into six types (first protrusion 1, second protrusion 2, third protrusion 3, fourth protrusion 4, fifth protrusion 5, and sixth protrusion 6) by focusing on the areas of the protrusions viewed in a direction perpendicular to backside surface 30 and the regions (central region or outer circumferential region) of the backside surface in which the protrusions were present, and the relationship between the area density of the six types of protrusions and the adsorption failure was investigated. As a result, it has been found that the occurrence of adsorption failure is significantly suppressed by controlling the relationship between the six types of protrusions as follows.

In silicon carbide epitaxial substrate 100 according to the embodiment of the present disclosure, when the area density of first protrusion 1 in central region 32 is denoted by Xa, the area density of second protrusion 2 in central region 32 is denoted by Xb, the area density of third protrusion 3 in central region 32 is denoted by Xc, the area density of fourth protrusion 4 in outer circumferential region 31 is denoted by Ya, the area density of fifth protrusion 5 in outer circumferential region 31 is denoted by Yb, and the area density of sixth protrusion 6 in outer circumferential region 31 is denoted by Yc, as viewed in the thickness direction of silicon carbide substrate 10, first protrusion 1 and fourth protrusion 4 each have an area of 100 μm² or more and less than 1,000 μm², second protrusion 2 and fifth protrusion 5 each have an area of 1,000 μm² or more and less than 5,000 μm², and third protrusion 3 and sixth protrusion 6 each have an area of 5,000 μm² or more. Backside surface 30 has a diameter of 100 mm or more, a value determined by dividing Xa by (Xa+Ya) is 0.3 or more and 0.5 or less, Xc is 10.0/cm² or less, and Yc is 12.0/cm² or less. Accordingly, adsorption failure of silicon carbide epitaxial substrate 100 can be suppressed.

In silicon carbide epitaxial substrate 100 according to the embodiment of the present disclosure, a value determined by dividing Xa by (Xa+Ya) may be 0.4 or less. Accordingly, the adsorption failure of silicon carbide epitaxial substrate 100 can be further suppressed.

### Examples

(Sample Preparation)

First, seven silicon carbide epitaxial substrates 100 having different values determined by dividing Xa by (Xa+Ya) were prepared. Silicon carbide epitaxial substrates 100 of samples 1 to 5 are examples. Silicon carbide epitaxial substrates 100 of samples 6 and 7 are comparative examples. In silicon carbide epitaxial substrates 100 of Samples 1 to 5, the value determined by dividing Xa by (Xa+Ya) was set to 0.3 or more and 0.5 or less. In silicon carbide epitaxial substrates 100 of Samples 6 and 7, the value determined by dividing Xa by (Xa+Ya) was set to be more than 0.5.

(Experimental Method)

Next, backside surface 30 of silicon carbide epitaxial substrate 100 of Samples 1 to 7 was adsorbed to a vacuum chuck (adsorption step). In the adsorption step, it was confirmed whether or not an adsorption error occurred. Next, the exposure step was performed on the samples in which no adsorption error occurred. In the exposure step, it was confirmed whether or not exposure failure occurred. It is considered that the exposure failure occurs when the adsorption is not sufficiently good although the adsorption error does not occur in the adsorption step.

(Experimental Results)

TABLE 1

| | | | | | | | Xa/ | Evaluation |
|---|---|---|---|---|---|---|---|---|
| | Xa | Xb | Xc | Ya | Yb | Yc | (Xa + Ya) | Result |
| Sample 1 | 202.3 | 7.8 | 0.8 | 339.0 | 8.0 | 2.2 | 0.37 | A |
| Sample 2 | 43.8 | 9.2 | 2.1 | 51.3 | 11.5 | 1.5 | 0.46 | B |
| Sample 3 | 287.6 | 5.3 | 0.4 | 549.5 | 4.1 | 1.0 | 0.34 | A |
| Sample 4 | 130.8 | 7.1 | 0.6 | 208.9 | 3.8 | 0.4 | 0.39 | A |
| Sample 5 | 9.8 | 0.5 | 0.1 | 16.2 | 1.9 | 0.8 | 0.38 | A |
| Sample 6 | 1038.5 | 28.0 | 4.1 | 683.7 | 38.6 | 4.7 | 0.60 | C |
| Sample 7 | 1079.8 | 111.1 | 8.3 | 893.4 | 78.7 | 10.6 | 0.55 | C |

Table 1 shows the evaluation results of silicon carbide substrate 10 of Samples 1 to 7. When no adsorption error occurred in the adsorption step and no exposure failure occurred in the exposure step, the evaluation result was evaluated as “A”. When no adsorption error occurred but exposure failure occurred in the exposure step, the evaluation result was “B”. When an adsorption error occurred in the adsorption step and the exposure step could not be performed, the evaluation result was “C”.

As shown in Table 1, when the value determined by dividing Xa by (Xa+Ya) was 0.3 or more and 0.5 or less, the evaluation result was “A” or “B”. When the value determined by dividing Xa by (Xa+Ya) was 0.3 to 0.4, the evaluation result was “A”. On the other hand, when the value determined by dividing Xa by (Xa+Ya) was more than 0.5, the evaluation result was “C”. From the above results, it was confirmed that the occurrence of the adsorption failure can be suppressed by setting the value determined by dividing Xa by (Xa+Ya) to 0.3 or more and 0.5 or less.

It should be understood that the embodiments and examples disclosed herein are illustrative in all respects and are not restrictive. The scope of the present invention is defined not by the above-described embodiments and examples but by the claims, and is intended to include meanings equivalent to the claims and all modifications within the scope.

### REFERENCE SIGNS LIST

1 first protrusion, 2 second protrusion, 3 third protrusion, 4 fourth protrusion, 5 fifth protrusion, 6 sixth protrusion, 7 first particle, 8 second particle, 9 downfall, 10 silicon carbide substrate, 13 orientation flat, 14 arc-shaped portion, 15 outer circumferential edge, 16 center, 17 first main surface, 18 second main surface, 20 first silicon carbide epitaxial layer (silicon carbide epitaxial layer), 21 third main surface, 30 backside surface, 31 outer circumferential region, 32 central region, 33 edge region, 40 second silicon carbide epitaxial layer, 50 susceptor, 51 first recess, 52 second recess, 53 third recess, 54 fourth recess, 55 fifth recess, 56 sixth recess, 57 seventh recess, 58 central portion, 59 top surface, 60 silicon carbide substrate placing member, 61 bottom surface, 62 side surface, 71 first defect, 72 second defect, 100 silicon carbide epitaxial substrate, 101 first direction, 102 second direction, H1 first height, H2 second height, H3 third height, H4 fourth height, H5 fifth height, H6 sixth height, R radius, T height, W1 first maximum width, W2 second maximum width, W3 third maximum width, W4 fourth maximum width, W5 fifth maximum width, W6 sixth maximum width, θ angle.

1. A silicon carbide epitaxial substrate comprising:
a silicon carbide substrate;
a silicon carbide epitaxial layer disposed on the silicon carbide substrate; and
a backside surface disposed opposite to the silicon carbide epitaxial layer with respect to the silicon carbide substrate,
wherein the backside surface includes a central region having a radius equal to ⅔ of a radius of the backside surface and surrounded by a circle centered at a center of the backside surface and an outer circumferential region surrounding the central region,
when an area density of a first protrusion present in the central region is denoted by Xa, an area density of a second protrusion present in the central region is denoted by Xb, an area density of a third protrusion present in the central region is denoted by Xc, an area density of a fourth protrusion present in the outer circumferential region is denoted by Ya, an area density of a fifth protrusion present in the outer circumferential region is denoted by Yb, and an area density of a sixth protrusion present in the outer circumferential region is denoted by Yc,
as viewed in a thickness direction of the silicon carbide substrate, the first protrusion and the fourth protrusion each have an area of 100 μm² or more and less than 1,000 μm², the second protrusion and the fifth protrusion each have an area of 1,000 μm² or more and less than 5,000 μm², and the third protrusion and the sixth protrusion each have an area of 5,000 μm² or more, and
the backside surface has a diameter of 100 mm or more, a value determined by dividing Xa by (Xa+Ya) is 0.3 or more and 0.5 or less, Xc is 10.0/cm² or less, and Yc is 12.0/cm² or less.

2. The silicon carbide epitaxial substrate according to claim 1, wherein Yb is 30.0/cm² or less.

3. The silicon carbide epitaxial substrate according to claim 1, wherein Xc is 3.0/cm² or less.

4. The silicon carbide epitaxial substrate according to claim 1, wherein Xb is 20.0/cm² or less.

5. The silicon carbide epitaxial substrate according to claim 1, wherein Yc is 4.0/cm² or less.

6. The silicon carbide epitaxial substrate according to claim 1, wherein the third protrusion and the sixth protrusion contain polycrystalline silicon carbide.

7. The silicon carbide epitaxial substrate according to claim 1, wherein the second protrusion and the fifth protrusion contain polycrystalline silicon carbide.

8. The silicon carbide epitaxial substrate according to claim 1, wherein the first protrusion and the fourth protrusion contain polycrystalline silicon carbide.

9. The silicon carbide epitaxial substrate according to claim 1, wherein the value determined by dividing Xa by (Xa+Ya) is 0.4 or less.
